(19) United States
(12) Patent Application Publication
(10) Pub. No.: US 2014/0183713 A1
(43) Pub. Date: Jul. 3, 2014

(54) DIE PACKAGE STRUCTURE

(71) Applicant: Innovative Turnkey Solution Corporation, Hsinchu City (TW)

(72) Inventor: Shih-Chi CHEN, Hsinchu City (TW)

(21) Appl. No.: 13/910,440

(22) Filed: Jun. 5, 2013

(30) Foreign Application Priority Data
Dec. 28, 2012 (TW) 101225505

(51) Int. Cl. H01L 23/495; H01L 23/498

(52) U.S. Cl. CPC H01L 23/49575; H01L 23/49861
USPC 257/676

(57) ABSTRACT

The die package structure includes a die, and the pads on one side of the active surface of the die. The connecting terminal is disposed on one side of the packaged substrate region and is passed through the packaged substrate region. The external connecting terminal is disposed on another side adjacent to the connecting terminal. The back surface of the packaged substrate region is fixed on the die by the adhesive layer, and the pad of the die is to be exposed. A conductive wire electrically connected the connecting terminal with the pads on the die. A packaged body encapsulated the packaged substrate region, the active surface of the die and the conductive wire, and the external connecting terminal is to be exposed. A conductive component is electrically connected with the connecting terminal and being exposed on the packaged body.

### FIELD OF THE INVENTION

The present invention relates to a die packaged structure which is formed by wafer level packaged process and simple wire bonding process, and in particular to a flash memory utilizes wire bonding process to form a die packaged structure.

### BACKGROUND OF THE INVENTION

The development of semiconductor technology is very fast, in particular, a semiconductor dices tends to miniaturization of the tendency. However, the function requirement of semiconductor dice also tends to the diversification. In other words, a smaller region of the semiconductor dice requires more input/out pads so as to the density of the pins is increased quickly. Thus, the semiconductor dices is difficult to package and the yield is to be decreased.

The mainly propose of the packaged structure is for preventing the die from the damage. However, each the plurality of dies is formed by cutting the wafer, and packaging and testing each the plurality of dies. In addition, another package technology is called “Wafer Level Package, WLP”, which is used to package the die on the wafer before the wafer is cut into a plurality dies. The wafer level package technology has several advantages such as short production cycle, lower cost, and no under-filler.

### SUMMARY OF THE INVENTION

The mainly objective of the present invention is to provide a die packaged structure, and a plurality of packaged substrate regions is formed on a circuit board. The plurality of packaged substrate regions on the circuit board is fixed on the wafer with a plurality of dies thereon by alignment process, such that a plurality of pads on one side of each plurality of dies on the wafer is electrically connected with the plurality of connecting terminals on the packaged substrate region by wire bonding process. Then, a plurality of external connecting terminals on the packaged substrate region is to be exposed after packaging process, and a plurality of die packaged structures with the circuit board can be obtained after sawing process.

Another objective of the present invention is to provide a die packaged structure, particularly to suitable for large scale die packaged process, such as memory, in particular to an NAND flash memory chip, NOR flash memory chip, communication IC chip, and several application-specific IC chip.

An objective of the present invention is to provide a die packaged structure. A plurality of external connecting terminals is exposed on one surface of the die packaged structure and is used as an external connecting endpoint to electrically connect another component. Another surface is the back surface of the die which is opposite to the plurality of external connecting terminals. Thus, the die packaged structure can achieve good heat dissipation effect, and good heat dissipation effect is very important for large scale IC.

According to above objectives, the present invention provides a die packaged structure, which includes a die having an active surface and a back surface, and a plurality of pads is disposed on one side of the active surface of the die. A packaged substrate region having a front surface and a back surface, a plurality of connecting terminals is disposed on one side of the packaged substrate region and is passed through the front surface and the back surface of the packaged substrate region, and a plurality of external connecting terminals is disposed on one side adjacent to the plurality of connecting terminals of the packaged substrate region, in which the back surface of the packaged substrate region is fixed on the die by an adhesive layer, such that the plurality of pads is exposed on one side of the die. A plurality of conductive wires is electrically connected the plurality of connecting terminals on one side of the packaged substrate region with the plurality of pads on one side of the die. A packaged body encapsulated the packaged substrate region, the active surface of the die and the plurality of conductive wires, and the plurality of external connecting terminals on one side of the packaged substrate region adjacent to the plurality of connecting terminals is to be exposed. A plurality of conductive components is electrically connected with the plurality of connecting terminals and is exposed on the packaged body.

The present invention also provides another die packaged structure, which includes a die having an active surface and a back surface, and a plurality of pads on one side of the active surface of the die. A packaged substrate region having a front surface and a back surface, a plurality of connecting terminals is disposed on one side of the packaged substrate region and is passed through the front surface and the back surface of the packaged substrate region, and a plurality of external connecting terminals is disposed on one side adjacent to the plurality of connecting terminals of the packaged substrate region, in which the back surface of the packaged substrate region is fixed on the die by an adhesive layer, such that the plurality of pads on one side of the die is to be exposed and the length of the plurality of external connecting terminals is extended outwardly larger than that of one side of the die. A plurality of conductive wires is electrically connected the plurality of connecting terminals on one side of the packaged substrate region with the plurality of pads on one side of the die. A packaged body encapsulated the packaged substrate region, the active surface of the die, and the plurality of conductive wires, and the plurality of external connecting terminals is exposed on outside of the packaged body.

### BRIEF DESCRIPTION OF THE DRAWINGS

The present invention will be apparent to those skilled in the art by reading the following description of a preferred embodiment thereof with reference to the drawings, in which:

FIG. 1 is a vertical view of the wafer having a plurality of dies thereon.

FIG. 2A is a vertical view of the front surface of the circuit board having a plurality of packaged substrate regions.

FIG. 28 is a vertical view of a back surface of the circuit board having a plurality of packaged substrate regions.

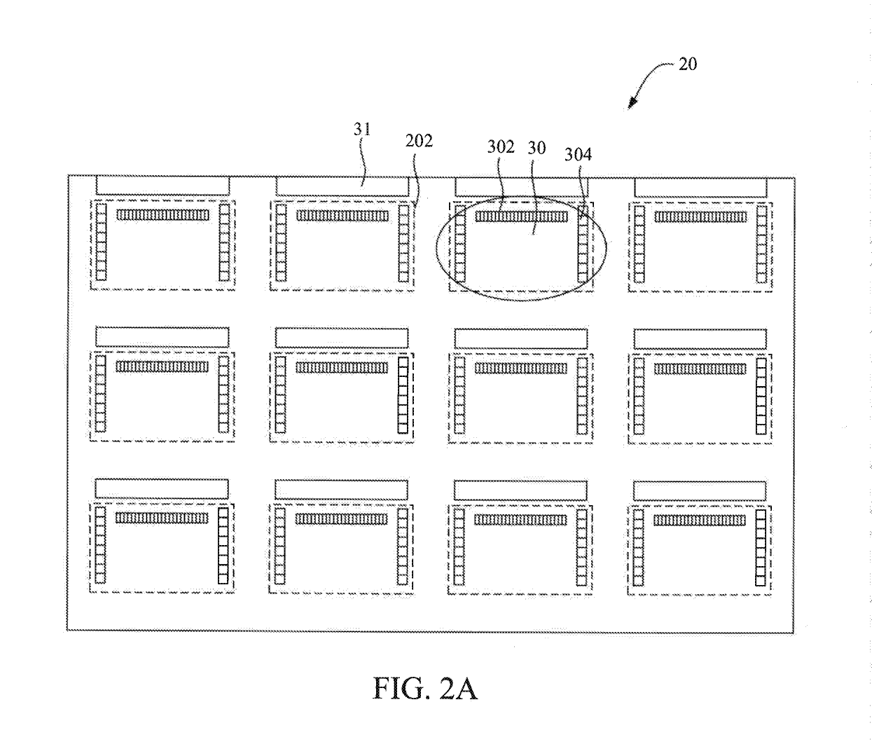

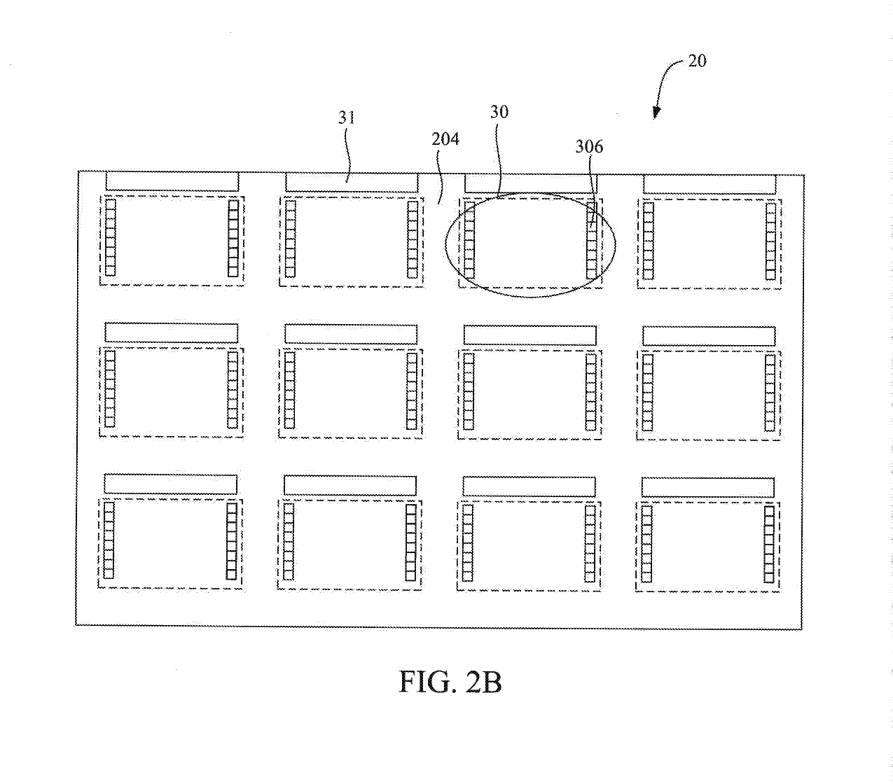

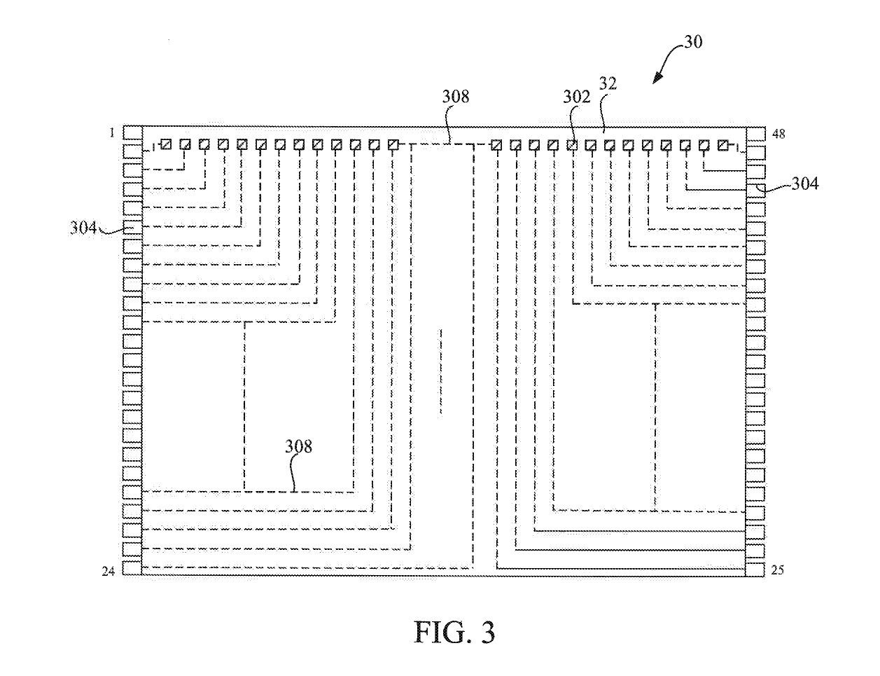

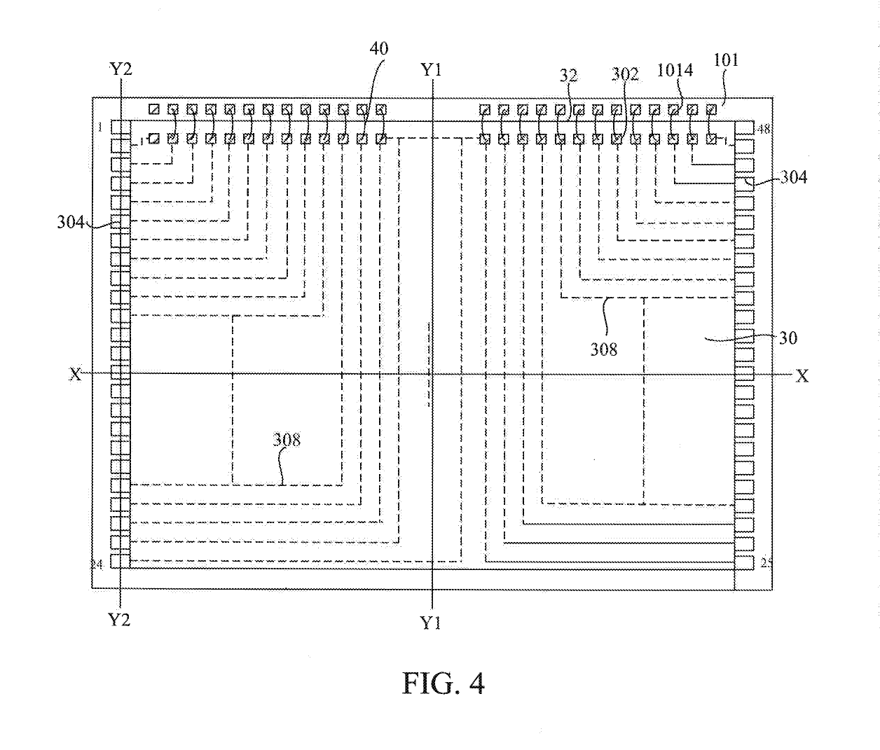

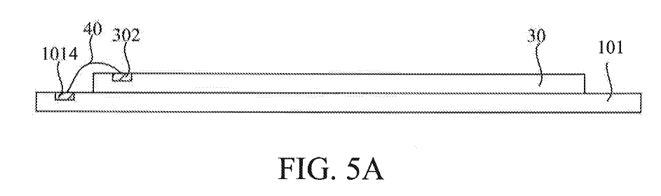

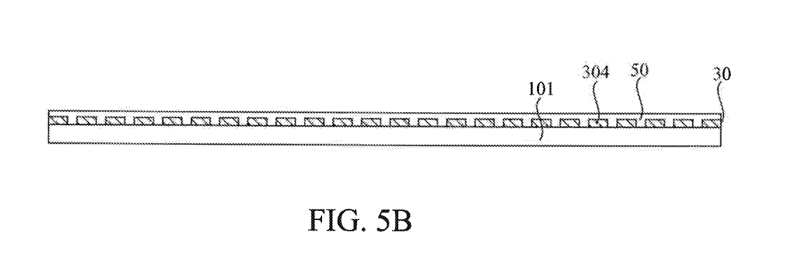

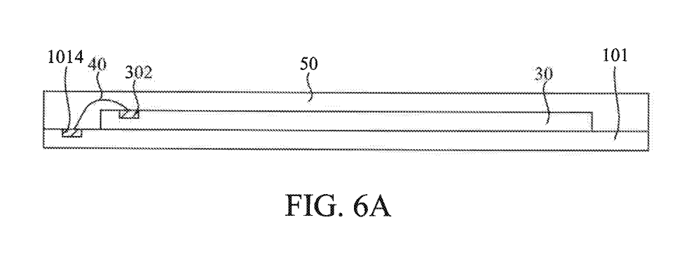

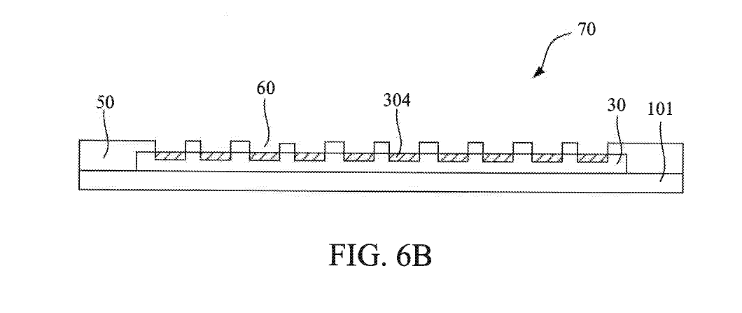

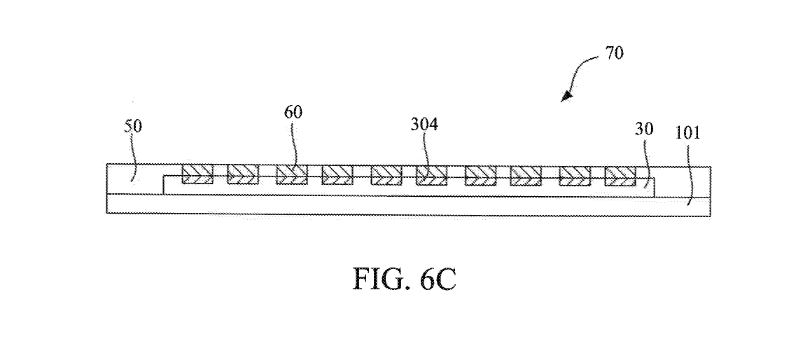

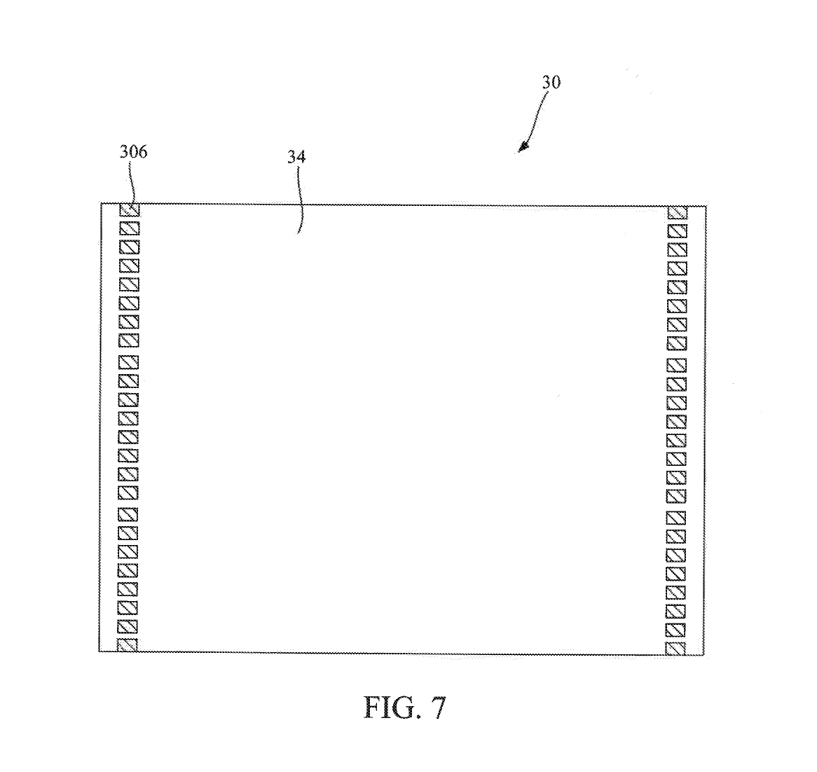

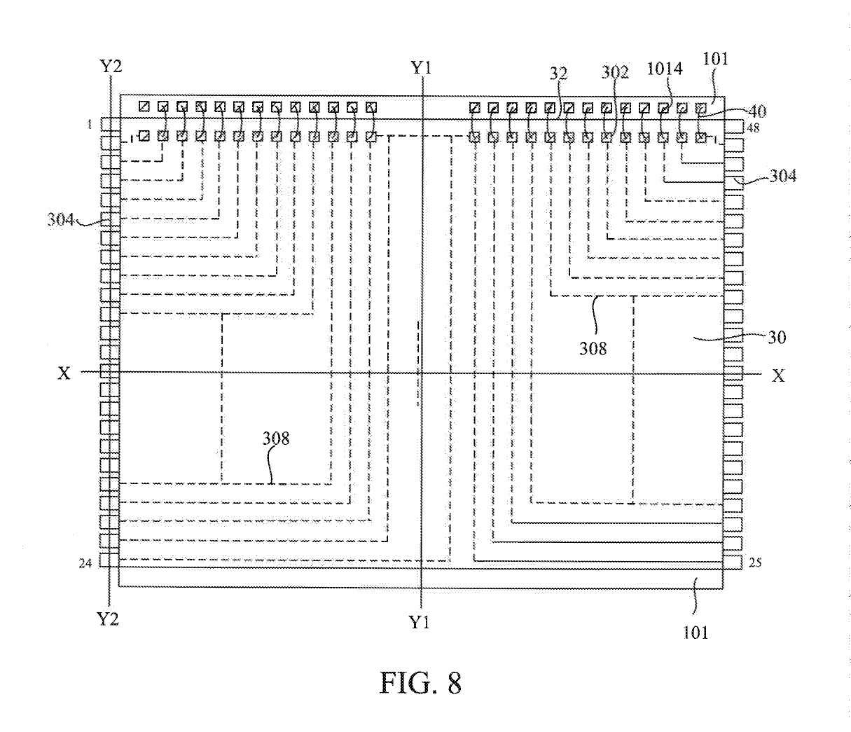

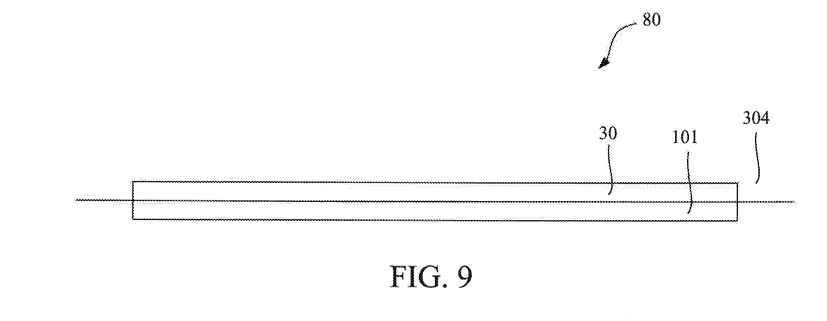

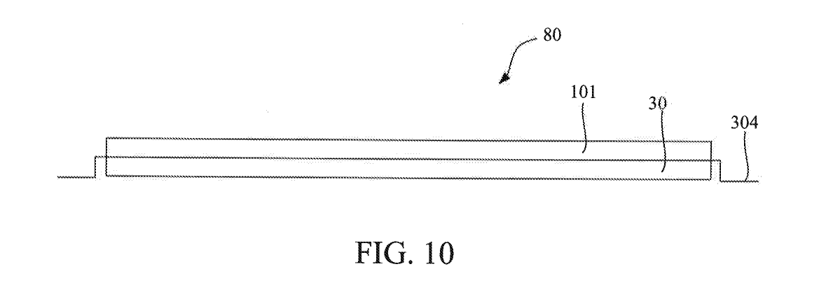

FIG. 3 is a vertical view of FIG. 2A of one of the plurality of packaged substrate regions of the circuit board having a plurality of connecting terminals and a plurality of traces.

FIG. 4 is a vertical view of the packaged substrate region is disposed on the die.

FIG. 5A is a cross-sectional view of Y1-Y1 direction in FIG. 4.

FIG. 5B is a cross-sectional view of Y2-Y2 direction in FIG. 4.

FIG. 6A is a cross-sectional schematic diagram illustrates a packaged material is formed on the packaged substrate region to encapsulate the packaged substrate region, the plurality of conductive wires, and the die in Y1-Y1 direction by screen printing process.

FIG. 6B is a cross-sectional schematic diagram illustrates a packaged material is formed on the packaged substrate region to encapsulate the packaged substrate region, the plurality of conductive wires and the die in Y2-Y2 direction by screen printing process.

FIG. 6C is a cross-sectional schematic diagram illustrate a plurality of conductive components disposed on the plurality of external connecting terminals of the packaged substrate region.

FIG. 7 is a vertical view of a back surface of the packaged substrate region after packaging process.

FIG. 8 is a vertical view of a die is disposed on the packaged substrate region.

FIG. 9 is a cross-section view of X-X direction in FIG. 8.

FIG. 10 is a cross-sectional view schematic diagram illustrate a plurality of leads of the die packaged substrate is formed by stamping process.

### DETAILED DESCRIPTION OF THE PREFERRED EMBODIMENT

The present invention provides a die packaged structure, in particular to a wafer level packaged structure is formed by using simple wire bonding process, and thus, such wafer level packaged structure can be referred to Wire-bonding Chip Scale Package (WBCSP), which can apply for large chip packaged structure. The cost can also be saved due to the simple packaged structure.

Some of the detail embodiments of the present invention will be described below. However, beside the detail description, the present invention can be generally used in other embodiments.

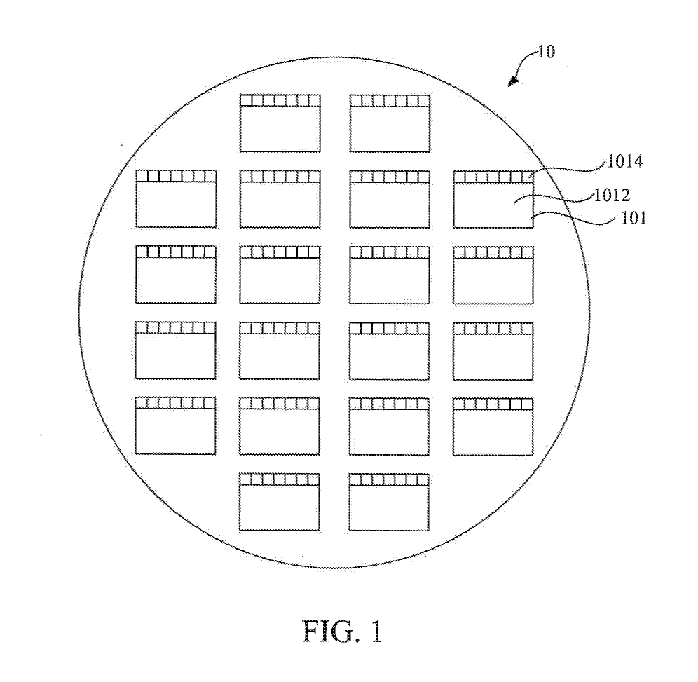

Please refer to FIG. 1. FIG. 1 is a vertical view of a wafer having a plurality of dies. As shown in FIG. 1, the wafer 10 having a plurality of dies 101. Each the plurality of dies 101 having an active surface 1012 and a back surface (not shown). A plurality of pads 1014 is disposed on one side of the active surface 1012 of the die 101, in which each the plurality of pads 1014 is formed by redistribution layer process. It is noted to illustrate that the plurality of dies 101 of the wafer 10 has completed the semiconductor manufacturing process, in which each the plurality of dies 101 such as NAND flash memory, NOR flash memory, communication IC or application-specific IC, which can be formed by large die manufacturing process.

In the embodiment of the present invention with the flash memory to illustrate, in particular to a NAND flash memory with 48 pins. In addition, the process and the redistribution layer process is not a main feature in this present invention, and thus it will not describe herein.

Then, please refer to FIG. 2A. FIG. 2A is a vertical view of a front surface of the circuit board having a plurality of packaged substrate regions. In FIG. 2A, a circuit board 20 is provided. The circuit board 20 having a front surface 202 and a back surface 204 (as shown in FIG. 2B). A plurality of packaged substrate regions 30 is arranged in array on the front surface 202 of the circuit board 20. A plurality of connecting terminals 302 is arranged on one side 32 of each the plurality of packaged substrate regions 30, and a plurality of external connecting terminals 304 is arranged on one side 34 adjacent to the plurality of connecting terminals 302. The plurality of connecting terminals 302 of the present invention can be golden finger structure or metal trace. When the plurality of connecting terminals 302 is golden finger, each the plurality of connecting terminals 302 can be isolated from each other by an insulating material (for example, plastic material) (not shown) or ceramic (not shown). In addition, the circuit board 20 can be a flexible print circuit board or a rigid substrate. Furthermore, for the rigid substrate, the circuit substrate 20 can be a single layer print circuit board (PCB) or a multilayer print circuit board. For the flexible print circuit board which can be made of polymeric material and lead frame. Moreover, an opening 31 is formed on one side adjacent to the plurality of connecting terminals 302 of each the plurality of packaged substrate regions 30 of the circuit board 20, and the opening 31 is used to expose the plurality of pads 1014 on one side of the die 101 after the packaged substrate region 30 is combined with the die 101.

Next, please refer to FIG. 2B. FIG. 2B is a vertical view of a back surface of the circuit board having a plurality of packaged substrate regions. In FIG. 2B, the back surface 204 of the circuit board 20 having a plurality of connecting terminals 306 thereon. The arrangement of the plurality of connecting terminals 306 corresponds to a plurality of connecting terminals 202 on the front surface of the circuit board 20, in which the plurality of connecting terminals 302 on the front surface 202 of the circuit board 20 is electrically connected with the plurality of connecting terminals 306 on the back surface 204 of the circuit board 20. It is noted to illustrate that the plurality of connecting terminals 302 and the plurality of connecting terminals 306 are the same connecting terminals, and are passed through the front surface 202 and the back surface 204 of the circuit board 20. In addition, the plurality of connecting terminals 306 on the back surface 204 of the circuit board 20 can be a pad or a bump.

Then, please refer to FIG. 3. FIG. 3 is a vertical view of FIG. 2A which illustrates one of the plurality of packaged substrate region having a plurality of connecting terminals and a plurality of traces thereon. In FIG. 3, the circuit board 20 having a plurality of packaged substrate regions 30, and one side 32 of the front surface 202 of each the plurality of packaged substrate regions 30 having a plurality of connecting terminals 302, and a plurality of external connecting terminals 304 is disposed on one side adjacent to the plurality of connecting terminals 302. The plurality of connecting terminals 302 is electrically connected with the plurality of external connecting terminals 304 by a plurality of traces 308.

Next, please referrer to FIG. 4. FIG. 4 is a vertical view of a circuit board disposed on the wafer. First, it is noted to that the formation steps of the die packaged structure is illustrated by one of the plurality of dies 101 of the wafer 10 and one of the plurality of packaged substrate regions 30. The die packaged structure is identical whether the die packaged structure is stacked by using a single packaged substrate region 30 and a die 20, or the die packaged structure is stacked by entire circuit board 20 and entire wafer 10. In the embodiment of the invention, the back surface 204 (it is also the back surface 204 of the circuit board 20) is fixed on the die 101 by an adhesive layer (not shown). The plurality of pads 1014 is exposed on an opening 31 which is disposed on one side 32 of the packaged substrate region 30, such that the plurality of pads 1014 is not encapsulated by the packaged substrate region 30. In addition, the length of the plurality of external connecting terminals 304 is larger than that of one side of the die 101 or is equal to that of one side of the die 101.

Please refer to FIG. 4. Each the plurality of connecting terminals 302 on the packaged substrate region 30 and the plurality of pads 1014 of the die 101 are exposed and are arranged in an array when the packaged substrate region 30 is fixed on the die 101. Then, the plurality of conductive wires 40 is formed on each the plurality of connecting terminals 302 on one side 32 of the packaged substrate region 30 and on each the plurality of pads 1014 on one side (now shown) of the die 101 respectively, such that the die 101 can electrically connect with corresponding packaged substrate region 30.

Please refer to FIG. 5A. FIG. 5A is a cross-sectional diagram of Y1-Y1 direction in FIG. 4. FIG. 5A is Y1-Y1 direction cross-sectional view of the packaged substrate region 30 which is arranged on the die 101. FIG. 5B is Y2-Y2 direction cross-sectional view of FIG. 4, which shows the plurality of external connecting terminals 304 that is disposed on the packaged substrate region 30 after wire bonding process is accomplished.

Please refer to FIG. 6A. FIG. 6A is a cross-sectional view of a packaged body that is encapsulated the packaged substrate region, a plurality of conductive wires and a die by using screen printing process. For example, such as the structure of FIG. 5A, the packaged material 50 is formed on the packaged substrate region 30 to encapsulate the plurality of conductive wires 40 and portion of active surface of the die 101 after wire bonding process is accomplished as shown in FIG. 6. Otherwise, FIG. 6B is a cross-sectional view of Y2-Y2 direction in FIG. 58 which shows the packaged material 50 that is formed on the packaged substrate region to encapsulate the packaged substrate region, the plurality of conductive wires, and the die after wire bonding process is accomplished. Obviously, the plurality of external connecting terminals 304 is exposed directly, that is, the packaged material is not formed to encapsulate the plurality of external connecting terminals 304. In alternative embodiment, the packaged material 50 is formed to encapsulate the plurality of external connecting terminals 304, and the plurality of external connecting terminals 304 is exposed by using semiconductor manufacturing process. The formation steps of the packaged material 50 is not to be limited in this invention, in addition, the material of the packaged material 50 is also not to be limited herein.

Please refer to FIG. 6C. FIG. 6C is a cross-sectional view of a plurality of conductive components is disposed on the plurality of external connecting terminals on the packaged substrate region. FIG. 6C is illustrated by using Y2-Y2 cross-sectional view of FIG. 6B. The plurality of conductive components 60 is formed on the plurality of external connecting terminals 304 of the packaged substrate region 30 by electroplating process after the screen printing process is finished to expose the plurality of external connecting terminals 304. The height of the plurality of conductive components 60 is larger than or equal to the total height of the packaged substrate region 30 and the packaged material 50. In addition, the plurality of conductive components 60 can be the bump which is formed by bump process.

It is noted to illustrate that although the die packaged structure is formed by a single a packaged substrate region 30 and a single die 101 according to above FIG. 2 to FIG. 6C, but in fact, the entire circuit board 20 is arranged on the entire wafer 10 during the packaging process. Thus, the entire wafer level packaged substrate can be finished after the plurality of conductive components 60 is formed on the plurality of external connecting terminals 304 on the circuit board 20 by electroplating process. Finally, the die packaged structure is cut into a plurality of die packaged structures 70 by sawing process. In this embodiment, the plurality of die packaged structures 70 is especially for flash NAND memory packaged structure.

Please refer to FIG. 7. FIG. 7 is a vertical view of a back surface of the packaged substrate region after completed the packaging process. Obviously, the plurality of external connecting terminals 304 is arranged inside of the die packaged structure 70. According to the die packaged structure 70, a plurality of external connecting terminals 304 is exposed on one side of the die packaged structure 70 to be the external connecting terminals. The back surface of the die 101 is opposites to the plurality of external connecting terminals 304 which use as the heat dissipation device, such that the die packaged structure can achieve good heat dissipating effect. The good heat dissipation effect is very important for the large scale IC.

In addition, the present invention also provides another embodiment. The manufacturing process is the same as above FIG. 1 to FIG. 6B as the above description, and it would not be described in detail herein. The different between the two embodiments is that the FIG. 8 is X-X direction cross-sectional view of FIG. 4. The packaged substrate region 30 with the plurality of external connecting terminals 304 is disposed on the die 101, in which the length of the plurality of external connecting terminals 304 is larger than that of the die 101. Next, please also refer to FIG. 9. The packaged material 60 is formed to encapsulate the packaged substrate region 30, the die 101, and the plurality of conductive wires 40 (not shown) and the plurality of external connecting terminals 304 on one side 32 of the packaged substrate region 30 is to be exposed by screen printing process. Because of FIG. 9 is X-X direction cross-sectional diagram of FIG. 8, and thus, FIG. 9 merely shows the cross-sectional view of the packaged substrate region 30 and the die 101, but the plurality of conductive wires is electrically connected the packaged substrate region 30 with the die 101 cannot be shown herein. In addition, because of entire circuit board 20 is arranged on the entire wafer 10, the sawing process can use to cut the wafer level packaged structure to obtain a plurality of die packaged structures 80.

Then, please refer to FIG. 10. FIG. 10 shows a plurality of external connecting terminals 304 of the packaged substrate region 30 is stamped by stamping process to form like a lead frame with an inner lead and an outer lead. For each the plurality of die packaged structures 80, each the plurality of die packaged structure 80 can electrically connect with other components (not shown), and the plurality of external connecting terminals 304 of each the plurality of die packaged structures 80 is stamped to form like a lead frame with the inner lead and the outer lead. Thus, the die packaged structure 80 can electrically connect with external component (not shown) via the lead frame with the inner lead and the outer lead.

Although the present invention has been described with reference to the preferred embodiment thereof, it is apparent to those skilled in the art that a variety of modifications and changes may be made without departing from the scope of the present invention which is intended to be defined by the appended claims.

What is claimed is:

1. A die packaged structure, comprising:
a die, said die having an active surface and a back surface, and a plurality of pads is disposed on one side of said active surface of said die;
a packaged substrate region, said packaged substrate region having a front surface and back surface, a plurality of connecting terminals disposed on one side of said packaged substrate region and is passed through said front surface and said back surface of said packaged substrate region, and a plurality of external connecting terminals is disposed on another side adjacent to said plurality of connecting terminals, wherein said back surface of said packaged substrate region is fixed on said die by an adhesive layer and said plurality of pads on said side of said packaged substrate region being exposed;
a plurality of conductive wires, said plurality of conductive wires is electrically connected said plurality of connecting terminals with said plurality of pads;
a packaged body, said packaged body encapsulated said packaged substrate region, said active surface of said die and said plurality of conductive wires and said plurality of external connecting terminals adjacent to said plurality of connecting terminals on said side of said packaged substrate region is exposed; and
a plurality of conductive components, said plurality of conductive components is electrically connected with said plurality of connecting terminals and is exposed on said packaged body.

2. The die package structure according to claim 1, wherein said packaged substrate region is a print circuit board.

3. The die package structure according to claim 1, wherein the size of said print circuit board is smaller than that of said die.

4. The die package structure according to claim 1, wherein said packaged substrate region is a flexible print circuit board.

5. The die package structure according to claim 1, wherein the size of said packaged substrate region is smaller than that of said die.

6. The die package structure according to claim 1, wherein height of said plurality of conductive components is equal to a total height of said packaged body.

7. A die package structure, comprising:
a die, said die having an active surface and a back surface, and a plurality of pads disposed on one side of said active surface of said die;
a packaged substrate region, said packaged substrate region having a front surface and a back surface, a plurality of connecting terminals disposed on one side of said packaged substrate region, and said plurality of connecting terminals passed through said front surface and said back surface of said packaged substrate region, a plurality of external connecting terminals disposed one side adjacent to said plurality of connecting terminals, wherein said back surface of said packaged substrate region is fixed with said die by an adhesive layer such that said plurality of pads exposed out of said side of said die and a length of said plurality of external connecting terminals is extended outwardly larger than said side of said die;
a plurality of conductive wires, said plurality of conductive wires is electrically connected said plurality of connecting terminals on said side of said packaged substrate region with said plurality of pads on said side of said die; and
a packaged body, said packaged body encapsulated said packaged substrate region, said active surface of said die and said plurality of conductive wires, and said plurality of external connecting terminals being exposed on an outside of said packaged body.

8. The die packaged structure according to claim 7, wherein said packaged substrate region is a print circuit board.

9. The die packaged structure according to claim 8, wherein a size of said packaged substrate region is smaller than that of said die.

10. The die packaged structure according to claim 7, wherein said packaged substrate region is a flexible print circuit board.

11. The die packaged structure according to claim 7, wherein a size of said packaged substrate region is smaller than that of said die.

12. The die packaged structure according to claim 7, wherein said plurality of external connecting terminals is a lead frame, and said lead frame includes an inner lead and an external lead.
